(19) United States
(12) Patent Application Publication
(10) Pub. No.: US 2020/0189622 A1
(43) Pub. Date: Jun. 18, 2020

(54) Inductive Sensor

(71) Applicant: Innova Patent GmbH, Wolfurt (AT)

(72) Inventors: Christoph Hofmayr, Dornbirn (AT); Adrian Mohni, St. Gallen (CH); Helmut Nagel, Höchst (AT)

(21) Appl. No.: 16/640,003

(22) PCT Filed: Aug. 23, 2018
(86) PCT No.: PCT/EP2018/072804

§ 371 Date: Feb. 18, 2020

(30) Foreign Application Priority Data
Aug. 25, 2017 (AT) A50711/2017

(51) Int. Cl. B61B 12/06; G01D 5/22; G01R 33/58

(52) U.S. Cl. CPC B61B 12/06; H03K 17/952; G01R 33/58; G01D 5/2216

(57) ABSTRACT

An inductive sensor insusceptible to external electromagnetic fields. The sensor coil is designed so as to have a first winding part and a second winding part connected thereto, the first winding part and the second winding part being wound in opposite directions. The first winding part is connected to a first coil terminal and the second winding part is connected to a second coil terminal.

### TECHNICAL FIELD

The present teaching relates to an inductive sensor comprising a sensor coil having two coil terminals and a sensor evaluation unit which is connected to the two coil terminals, and the use of a sensor of this kind for monitoring the position of a cable of a cable car system.

### BACKGROUND

Contactless inductive sensors are often used for distance measurement. In this case, the sensor can be designed as a proximity sensor that works from a certain distance of the sensor from the measured object, or the distance from the object can also be output by the sensor as a value. Sensors of this kind are often used to monitor particular functionalities in machines and systems.

An inductive sensor uses a coil to generate an electromagnetic field which is influenced by the measured object. The influence can be recorded and evaluated using measurement technology. One exemplary embodiment is an inductive sensor designed as an eddy current sensor. In this case, an oscillator generates an electromagnetic alternating field that emanates from the active surface of the sensor. Eddy currents are induced in each electrically conductive object in the vicinity of the active surface depending on the distance of the object from the active surface, which eddy currents draw energy from the oscillator and can be detected as power losses at the coil input.

One particular application for an inductive sensor is monitoring the position of the circulating traction cable of a cable car system. The traction cable is guided along the route on the cable car supports via rollers of a roller battery. The position of the traction cable relative to the rollers of the roller battery can be monitored using an inductive sensor. In so doing, it is possible to identify both the lateral deflection of the traction cable, which can indicate, for example, the traction cable popping out of the roller, and an insufficient distance from the axis of rotation of the roller, which indicates that the traction cable is eating into the running surface of the roller, for example when the roller is blocked. Monitoring the position of the cable is an important safety function of a cable car system and can lead to a reduction in the conveying speed or to a forced shutdown of the cable car. When monitoring the position of the cable, the traction cable which is designed as a steel cable is used as the object to be measured and the sensor is arranged so as to be stationary in the region of the traction cable. This application requires high sensitivity of the inductive sensor in order to be able to detect the position of the cable with sufficient accuracy.

Inductive sensors of this kind are disadvantageous in that each external (electro)magnetic alternating field in the vicinity of the sensor induces an electrical voltage in the coil of the sensor. This overvoltage impressed from the outside of course also interferes with the measurement. Besides this, the sensor must of course also have sufficient overvoltage resistance. Radio waves in the vicinity of the sensor will only induce low voltages and will primarily negatively influence the measurement and reduce the sensitivity of the measurement. However, if lightning strikes the traction cable of the cable car, this creates a current flow in the traction cable, thereby generating strong magnetic fields around the traction cable. Lightning currents of this kind can cause very high electrical voltages to be injected into the coil of the sensor. Studies have shown that, in the event of typical lightning currents, induced voltages of several kilovolts can occur at the outlets of the coil. These high voltages can destroy the coil and/or destroy the subsequent sensor electronics.

Of course, it is possible to implement electronic lightning protection or protection against overvoltage in the sensor, but this in turn interferes with the measuring circuit and thus limits the sensitivity of the sensor.

### SUMMARY

One problem addressed by the present teaching is therefore that of providing an inductive sensor which is insusceptible to external electromagnetic fields.

This problem is solved by the sensor coil being designed so as to have a first winding part and a second winding part connected thereto, the first winding part and the second winding part being wound in opposite directions and the first winding part being connected to a first coil terminal and the second winding part being connected to a second coil terminal. By means of winding in opposite directions, voltages induced in the winding parts compensate for one another at least in part, and therefore only low or no overvoltages can occur at the coil terminals. This does not interfere or only slightly interferes with the measurement such that a high sensitivity of the measurement can be achieved. Likewise, further measures for overvoltage protection against overvoltage caused by external electromagnetic fields, which measures could interfere with the measuring circuit, are not required. This means that the sensor can also be protected against very high external electromagnetic fields, such as can occur in the event of lightning currents through conductors, for example. A sensor of this kind is therefore particularly suitable for outdoor applications. A particularly advantageous application for a sensor of this kind is therefore use in a cable car system, for example for monitoring the position of the traction cable.

In one simple embodiment, the sensor coil is continuously wound in a figure of eight. A sensor coil of this kind is particularly easy to manufacture.

A sensor coil which comprises a first single coil as the first winding part that is connected in series with a second single coil as the second winding part is particularly advantageous. By means of this embodiment, high differential voltages between individual windings of the sensor coil can be avoided, which reduces the risk of voltage breakdowns.

If the first single coil and the second single coil are wound helically, a particularly flat sensor coil can be created, which is advantageous for use in the sensor.

### BRIEF DESCRIPTION OF THE DRAWINGS

In the following, the present teaching will be explained in greater detail with reference to FIGS. 1 to 5, which show exemplary advantageous embodiments of the present teaching in a schematic and non-limiting manner. In the drawings:

FIG. 1 shows the operating principle of a contactless inductive sensor;

FIG. 2 shows a first embodiment of a sensor coil according to the present teaching;

FIG. 3 shows a further embodiment of a sensor coil according to the present teaching;

FIG. 4 shows a further embodiment of a sensor coil according to the present teaching; and

FIG. 5 shows the use of a sensor coil according to the present teaching for monitoring the position of a cable in a cable car system.

### DETAILED DESCRIPTION

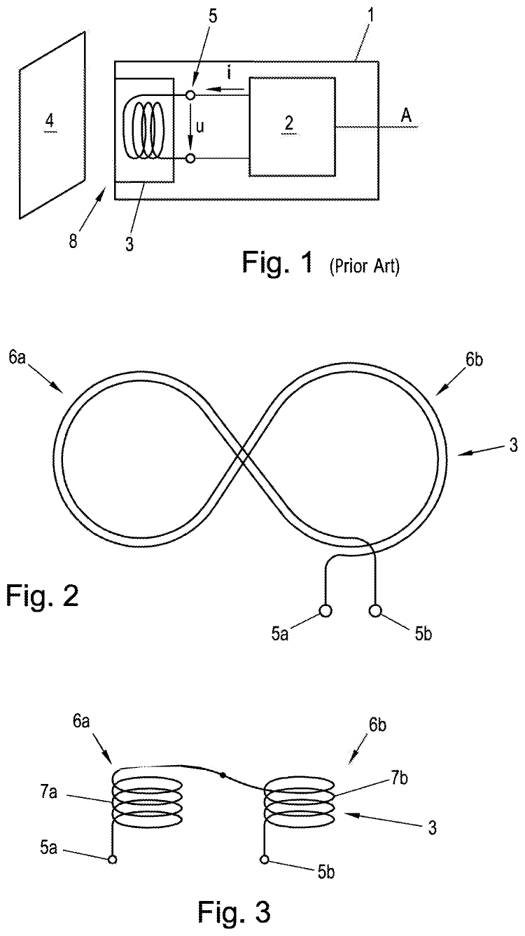

The principle of an inductive sensor for distance measurement is shown in FIG. 1. A sensor coil 3 generates an electromagnetic field which interacts with an electrically conductive object 4. This interaction can be detected and evaluated at the outlets 5 of the sensor coil 3 by a sensor evaluation unit 2, for example via the coil voltage u and/or the coil current i. In one embodiment as an eddy current sensor, an oscillator in the sensor evaluation unit 2 generates a high-frequency alternating voltage which is applied to the sensor coil 3 and generates a high-frequency alternating field. This high-frequency alternating field generates eddy currents in an object 4 in the region of influence of the sensor 1, which currents draw energy from the electromagnetic alternating field, thereby reducing the height of the oscillation amplitude of the oscillator voltage. This change in oscillation amplitude is evaluated by the sensor evaluation unit 2. If embodied as a proximity switch, the sensor 1 either supplies a high level or low level as an output signal A or the output signal A represents a measure of the distance between the sensor coil 3 and the object 4. In the latter case, the output signal A can be analog, for example an electrical voltage, or digital.

However, the principle according to which the inductive sensor 1 operates or how the sensor evaluation unit 2 is designed or how it is evaluated or in what way the output signal A is output is irrelevant to the present teaching.

The present teaching is based on a particular embodiment of the sensor coil 3. According to the present teaching, the sensor coil 3 is designed so as to have a first winding part 6a and a second winding part 6b connected thereto, the first winding part 6a and the second winding part 6b being wound in opposite directions. A first coil terminal 5a is connected to the first winding part 6a and a second coil terminal 5b is connected to the second winding part 6b. As a result of winding the two winding parts 6a, 6b in opposite directions, external electromagnetic fields induce opposite voltages in the two winding parts 6a, 6b, which voltages compensate for one another at least in part. In this way, a significantly lower overvoltage is produced by external electromagnetic fields at the coil terminals 5a, 5b. If the two winding parts 6a, 6b are identical except for the winding direction, the voltages induced therein substantially cancel one another out and there are no or only extremely low overvoltages at the coil terminals 5a, 5b. This applies at least to a homogeneous external electromagnetic field, but can usually be assumed for typical applications. However, even in the case of an inhomogeneous external field, the two induced voltages would largely compensate for one another.

The sensor coil 3 can be wound continuously or can also consist of two single coils connected in series.

In a first embodiment according to FIG. 2, the sensor coil 3 is continuously wound in a figure of eight. For the sake of simplicity, only two windings per winding part 6a, 6b are shown in FIG. 2, but the sensor coil 3 can of course also have more windings. As a result of the figure-of-eight-shaped winding, the two resulting winding parts 6a, 6b have opposite winding directions.

A similar result is obtained by first winding a coil, compressing the wound coil at one point and then rotating one of the resulting winding parts 6a by 180° with respect to the other winding part 6b. This likewise produces a continuously wound figure-of-eight-shaped sensor coil 3 which has two winding parts 6a, 6b wound in opposite directions.

A further embodiment is produced when two single coils 7a, 7b wound in opposite directions are connected in series. In this case, the two single coils 7a, 7b each form a winding part 6a, 6b in the sensor coil 3, as shown in FIG. 3.

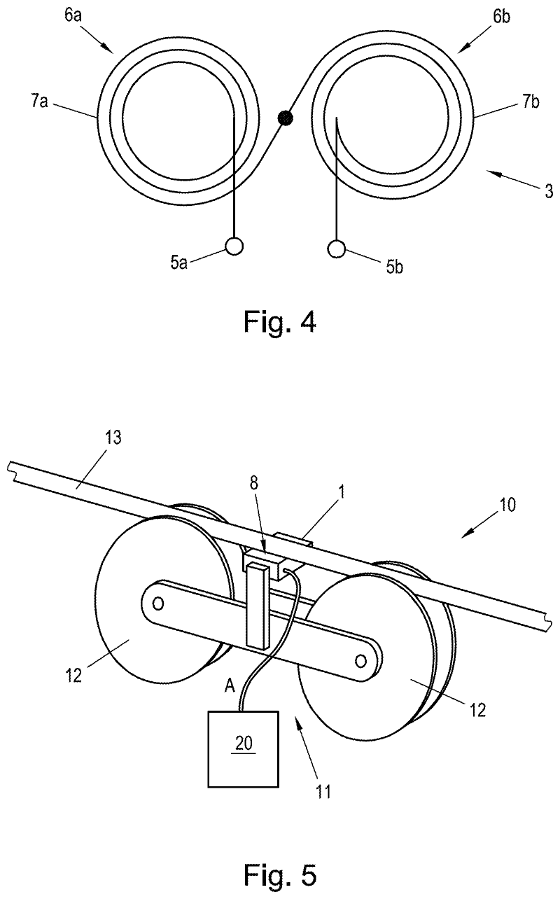

In one particularly advantageous embodiment, the two single coils 7a, 7b forming the winding parts 6a, 6b are wound helically, as shown in FIG. 4. In this case, the windings of the winding parts 6a, 6b are preferably arranged in one plane. The winding parts 6a, 6b can in this case be wound as a single-layer helix or also as a multi-layer helix. In an embodiment of this kind, the sensor coil 3 can be particularly flat.

The advantage of the embodiment comprising single coils 7a, 7b connected in series compared to a continuously wound sensor coil 3 is that the voltage differences between adjacent windings of the sensor coil 3 are always small, and therefore no undesirable voltage breakdowns can occur which would destroy the sensor coil 3. In the case of a figure-of-eight-shaped embodiment, there may be large voltage differences between individual windings, in particular in the region of the crossing point of the individual windings, for which reason the risk of voltage breakdowns is higher in this case and therefore higher insulation measures have to be taken according to the circumstances.

In order to avoid the electromagnetic excitation fields generated by the winding parts 6a, 6b not completely or partially cancelling one another out, the two winding parts 6a, 6b are arranged one next to the other in one plane, as shown in the figures, and not one behind the other. This plane is also referred to as the active surface 8 (FIG. 1) of the sensor 1, from which surface the electromagnetic fields emanate. In this case, the object 4 is arranged opposite the active surface 8 of the sensor 1 in order to reach the region of influence of the electromagnetic fields.

The sensor 1 can also be used in safety-critical applications, and therefore the sensor 1 can also be designed to meet functional safety requirements (e.g. a safety requirement level in accordance with IEC 61508). For example, the sensor 1 could be designed so as to have a two-channel sensor evaluation unit 2, it also being possible to provide mutual checks on the channels. Of course, other or additional known measures for achieving functional safety are also conceivable.

One advantageous application of the inductive sensor 1 according to the present teaching is monitoring the position of a cable of a cable car system 10, as shown in FIG. 5. The cable car system 10 is only shown in part and as far as necessary in FIG. 5, since the basic structure of a cable car system in various embodiments is well known. In this case, the sensor 1 is arranged, for example, so as to be stationary in the region of a roller battery 11 on a cable car support comprising a number of cable rollers 12 and so as to be in contactless operative connection with a traction cable 13. Of course, the sensor 1 can also be arranged at any other point in the cable car system 10 in order to monitor the position of the traction cable 13. ‘In operative connection’ in this case means, of course, that the traction cable 13, as the object 4, sufficiently influences the electromagnetic field of the sensor coil 3 of the sensor 1 that a change in position of the traction cable 13 relative to the sensor 1 can be detected and evaluated by the sensor evaluation unit 2. For this purpose, the traction cable 13 is arranged opposite the active surface 8 of the sensor 1. The output signal A from the sensor 1 is transmitted to a cable car control unit 20 and used in said unit to control the cable car system 10. The transmission can, of course, be wired or wireless. For example, depending on the output signal A, the conveying speed of the traction cable 13 can be changed, or the cable car system 10 can be stopped.

1. An inductive sensor for monitoring the position of a traction cable of a cable car system, the sensor comprising a sensor coil having two coil terminals and a sensor evaluation unit which is connected to the two coil terminals, wherein the sensor coil is designed so as to have a first winding part and a second winding part connected thereto, the first winding part and the second winding part being wound in opposite directions and the first winding part being connected to a first coil terminal and the second winding part being connected to a second coil terminal, and the sensor coil is designed to be operatively connected to the traction cable and the sensor evaluation unit is designed to detect and evaluate a change in position of the traction cable relative to the sensor.

2. The inductive sensor according to claim 1, wherein the sensor coil is continuously wound in a figure of eight.

3. The inductive sensor according to claim 1, wherein a first single coil as the first winding part is connected in series with a second single coil as the second winding part.

4. The inductive sensor according to claim 3, wherein the first single coil and the second single coil are wound helically.

5. The inductive sensor according to claim 1, wherein the two winding parts are arranged one next to the other in one plane.

6. A cable car system comprising a traction cable and an inductive sensor according to claim 1 for monitoring the position of a the traction cable.
